(19) United States
(12) Patent Application Publication
(10) Pub. No.: US 2013/0119227 A1
(43) Pub. Date: May 16, 2013

(54) HAND-HELD SUPPORT FOR A PORTABLE ELECTRONIC PRODUCT

(71) Applicant: Paul LIN, Tainan City (TW)

(72) Inventor: Paul LIN, Tainan City (TW)

(21) Appl. No.: 13/295,910

(22) Filed: Nov. 14, 2011

(51) Int. Cl. H05K 7/00

(52) U.S. Cl. 248/689

(57) ABSTRACT

A hand-held support is adapted for supporting a portable electronic product. The hand-held support includes a grip, a clamping seat for clamping the electronic product, and a connecting mechanism for interconnecting the grip and the clamping seat in such a manner to allow for adjustment of a relative angle between the grip and the clamping seat. The clamping seat includes a clamping wall having two clamping portions that are opposite to each other and that are adapted to contact respectively two opposite sides of the electronic product for clamping the electronic product therebetween, and a base portion interconnecting the clamping portions.

### BACKGROUND OF THE INVENTION

1. Field of the Invention

The invention relates to a hand-held support, more particularly to a hand-held support adapted for supporting a portable electronic product, such as a personal digital assistant (abbreviated as PDA), a tablet computer, etc.

2. Description of the Related Art

Typically, computers are designed to have different shapes and sorts for providing different functionalities and meeting distinct needs. For example, a desktop computer is placed at a fixed location, whereas a notebook computer, though having functionalities similar to the desktop computer, is designed to be more light-weighted and capable of storing electric power so as to be carried around. In addition, portable electronic products (such as personal digital assistants, tablet computers, etc.) have even smaller volumes and weights than the notebook computer, so that they are more suitable for gripping when in use.

Though the portable electronic products are suitable for gripping, nevertheless, under consideration of easy operations, they typically have significantly larger surface areas than ordinary mobile phones. As such, though the portable electronic product has characteristics of lightweight and compact dimension, it is inconvenient to be held by a single hand. Moreover, if these sorts of portable electronic products are placed on a desk top, since the display panels thereof face upwardly, the portable electronic products cannot be operated conveniently.

### SUMMARY OF THE INVENTION

Therefore, the main object of the present invention is to provide a hand-held support that is capable of supporting a portable electronic product and that permits a single hand to hold easily, so as to result in convenience during operation of the portable electronic product.

Accordingly, a hand-held support of the present invention is adapted for supporting a portable electronic product. The electronic product has two opposite sides. The hand-held support comprises a grip, a clamping seat adapted for clamping the electronic product in such a manner to allow the electronic product to be removed forcibly therefrom, and a connecting mechanism for interconnecting the grip and the clamping seat in such a manner to allow for adjustment of a relative angle between the grip and the clamping seat. The clamping seat includes a clamping wall having two clamping portions that are opposite to each other and that are adapted to contact respectively the sides of the electronic product for clamping the electronic product therebetween, and a base portion interconnecting the clamping portions.

Preferably, the clamping seat further includes a pivot block, the grip includes a pivot head, and the connecting mechanism includes a connecting block, a first pivot pin extending through the pivot block of the clamping seat and the connecting block, and a second pivot pin extending rotatably through the pivot head of the grip and the connecting block. Alternatively, the connecting mechanism includes an engaging block disposed on one of the grip and the clamping seat, and a ball disposed on the other of the grip and the clamping seat. The engaging block is formed with an engaging groove for engagement with the ball to constitute a universal joint.

Preferably, the first and second pivot pins are perpendicular to each other.

Preferably, the base portion of the clamping wall is formed with a plurality of open-ended slots so as to increase resilience of the clamping portions.

Preferably, the base portion of the clamping seat has opposite front and rear side surfaces. The front side surface is adapted for contact with the electronic product. The open-ended slots are formed in the front and rear side surfaces.

Preferably, the clamping seat further includes at least one pad attached fixedly to the clamping seat and extending across a junction between the base portion and one of the clamping portions.

Preferably, each of the clamping portions of the clamping seat is formed with a retaining flange that is disposed at an end thereof distal from the base portion and that has an engaging surface, which faces the front side surface and which is adapted for contact with the electronic product.

The hand-held support of this invention has a advantage. That is, when the portable electronic product is clamped by the hand-held support, an assembly of the hand-held support and the portable electronic product can be held with ease or to be placed on a supporting surface in such a manner that a display panel of the portable electronic product is at an inclined position, so as to result in convenience during operation of the portable electronic product.

### BRIEF DESCRIPTION OF THE DRAWINGS

Other features and advantages of the present invention will become apparent in the following detailed description of the preferred embodiments with reference to the accompanying drawings, of which:

FIG. 1 is an exploded front perspective view of the first preferred embodiment of a hand-held support for a portable electronic product according to the present invention;

FIG. 2 is a schematic view of the first preferred embodiment for illustrating connection relation between the hand-held support and the portable electronic product;

FIG. 3 is a fragmentary rear perspective view of the first preferred embodiment for illustrating a connecting mechanism;

FIG. 4 is a side view of the first preferred embodiment for illustrating that the hand-held support is used to support the portable electronic product on a horizontal supporting surface;

FIG. 5 is a top view similar to FIG. 2, illustrating a relative angle between a clamping seat and a grip, which is different from that illustrated by FIG. 2; and

FIG. 6 is a side view of the second preferred embodiment of a hand-held support for a portable electronic product according to the present invention.

### DETAILED DESCRIPTION OF THE PREFERRED EMBODIMENTS

Before the present invention is described in greater detail with reference to the preferred embodiments, it should be noted herein that accompanying drawings are for use in reference and illustration, and hence should not be used to impose implementation restriction of this invention, and, like elements are denoted by the same reference numerals throughout the disclosure.

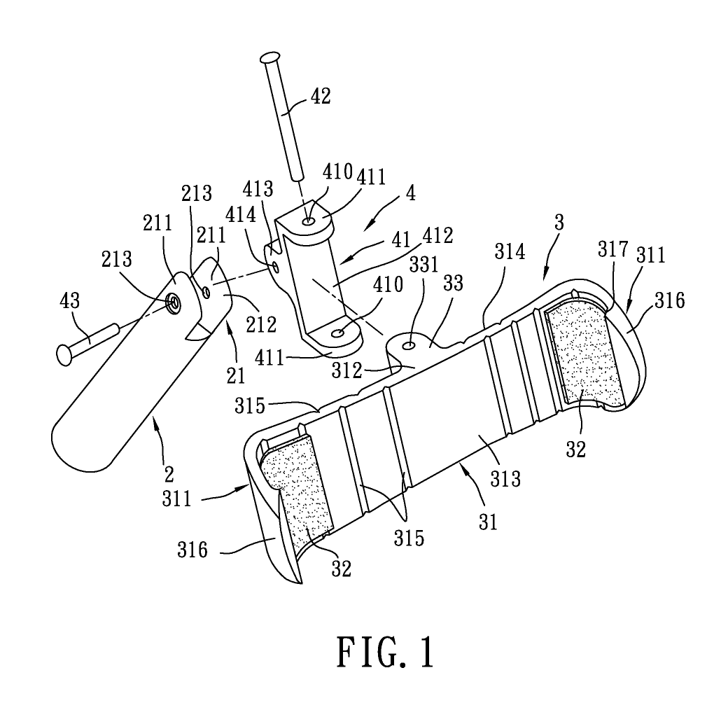

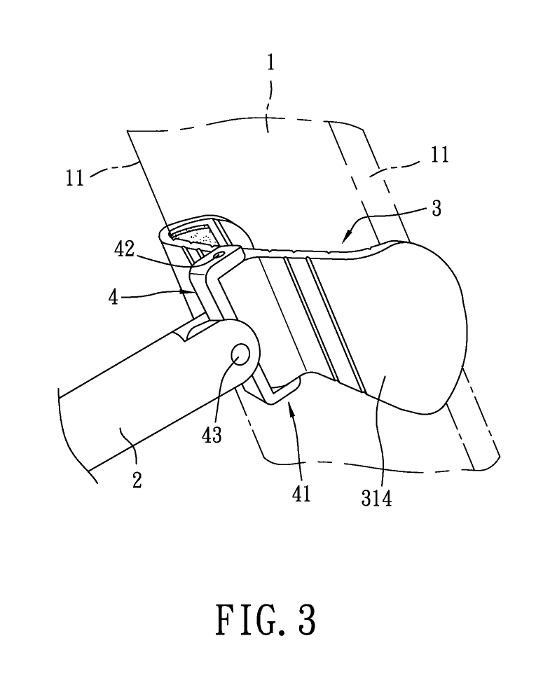

Referring to FIGS. 1 to 3, the first preferred embodiment of a hand-held support according to the present invention is shown to be adapted for supporting a portable electronic product 1. The portable electronic product 1 is rectangular, and includes two opposite sides 11. The hand-held support comprises a grip 2 suitable for a hand to grip, a clamping seat 3 adapted for clamping the electronic product 1 in such a manner to allow the electronic product to be removed forcibly therefrom, and a connecting mechanism 4 for interconnecting the grip 2 and the clamping seat 3 in such a manner to allow for adjustment of a relative angle between the grip 2 and the clamping seat 3.

The grip 2 in this embodiment is configured as a rod, preferably a circular rod, and includes a pivot head 21. The pivot head 21 has a pair of aligned protruding walls 211 that cooperate to define a groove 212 therebetween. Each of the protruding walls 211 is formed with a first mounting hole 213.

The clamping seat 3 includes an elongate clamping wall 31 having two clamping portions 311 that are opposite to each other and that are adapted to contact respectively the sides 11 of the portable electronic product 1 for clamping the portable electronic product 1 therebetween, abase portion 312 interconnecting the clamping portions 311, a pair of pads 32 spaced apart from each other and each attached fixedly to the clamping seat 3 and extending across a junction between the base portion 312 and a respective one of the clamping portions 311, and a pivot block 33 extending from the clamping wall 31 toward the grip 2. The base portion 312 of the clamping seat 3 has opposite front and rear side surfaces 313, 314. The front side surface 313 is adapted for contact with the portable electronic product 1. A plurality of open-ended slots 315 are formed in the front and rear side surfaces 313, 314, and extend along a direction parallel to the sides 11 of the portable electronic product 1, so as to increase resilience of the clamping portions 311. Each of the clamping portions 311 of the clamping seat 3 is formed with a retaining flange 316 that is disposed at an end thereof distal from the base portion 312 and that has an engaging surface 317, which faces the front side surface 313 and which is adapted for contact with the portable electronic product 1.

Alternatively, the clamping seat 3 may include only one pad 32, which covers the whole base portion 312 and the whole clamping portions 311 for protecting the portable electronic product 1. The pivot block 33 extends from the rear side surface 314, and is formed with a first pivot hole 331 extending along a direction transverse to a longitudinal direction of the base portion 312.

In this embodiment, the connecting mechanism 4 of the hand-held support includes a connecting block 41, a first pivot pin 42 extending through the pivot block 33 of the clamping seat 3 and the connecting block 41, and a second pivot pin 43 extending rotatably through the pivot head 21 of the grip 2 and the connecting block 41. The connecting block 41 includes a pair of claming-seat connecting portions 411, each of which is formed with a second mounting hole 410, a connecting plate portion 412 interconnecting the clamping-seat connecting portions 411, and a grip connecting portion 413 protruding from the connecting plate portion 412 in a direction away from the clamping-seat connecting portions 411 and formed with a second pivot hole 414. The first pivot pin 42 extends through the second mounting holes 410 of the connecting block 41 and the first pivot hole 331 of the clamping seat 3. The second pivot pin 43 extends through the second pivot hole 414 of the grip connecting portion 413 and the first mounting holes 213 of the grip 2. In this embodiment, the first and second pivot pins 42, 43 are perpendicular to each other.

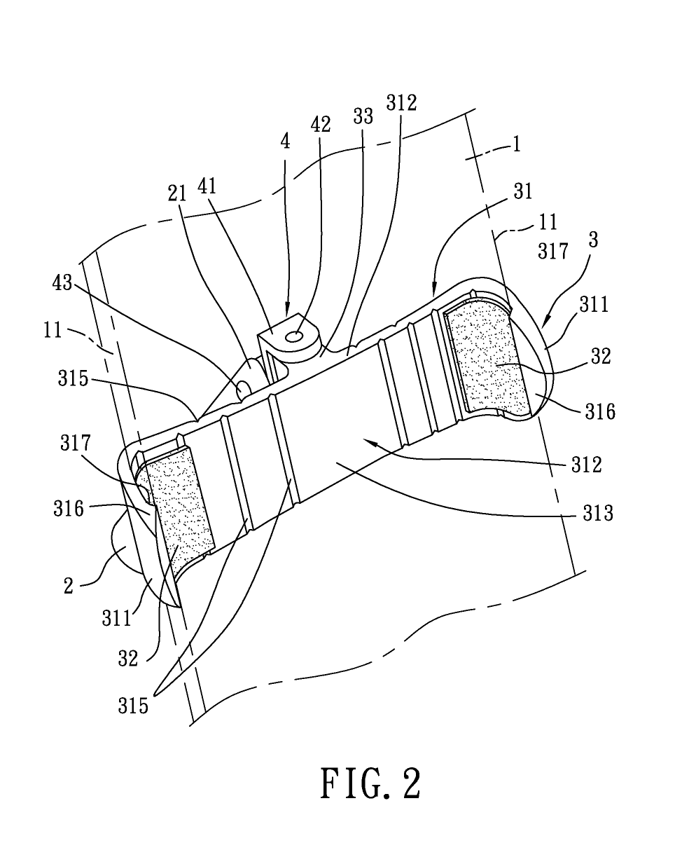

Referring to FIGS. 2, 4 and 5, when the hand-held support of this invention is in use, the opposite sides of the portable electronic product 1 abut respectively against the inner sides of the clamping portions 311 of the clamping seat 3. The portable electronic product 1 is clamped between the front side surface 313 of the clamping seat 3 and the engaging surfaces 317. Since the clamping wall 31 are not only formed with the resilient open-ended slots 315, but also provided with the pads 32, the portable electronic product 1 can be firmly clamped on the clamping seat 3. After the portable electronic product 1 is mounted to the hand-held support, a user can hold the grip 2 with one hand, and then moves or uses the portable electronic product 1 at will. Due to the presence of the connecting mechanism 4 interconnecting the grip 2 and the clamping seat 3, the relative angle between the grip 2 and the clamping seat 3 can be changed to adjust the inclination angle of a display panel of the portable electronic product 1 according to needs.

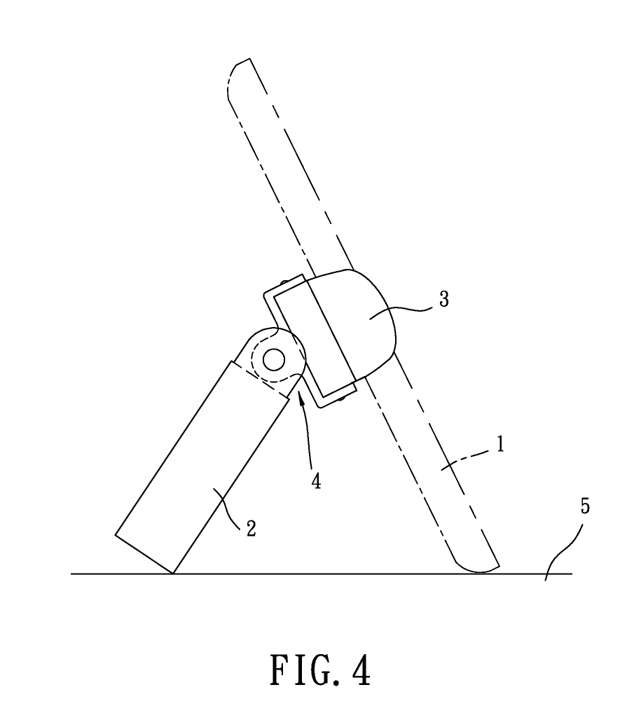

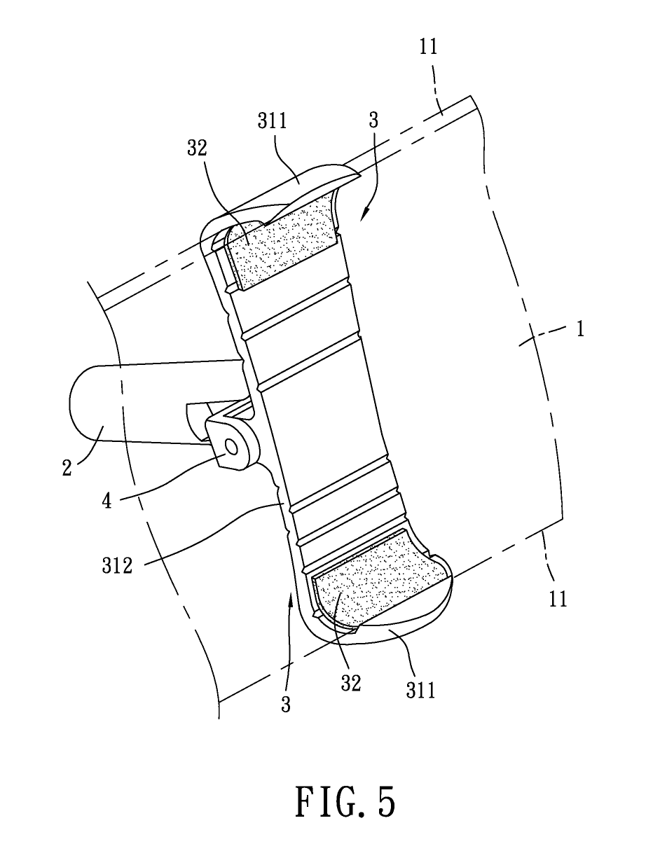

Apart from being gripped for use, the hand-held support of this invention can be used in a manner as illustrated in FIG. 4, in which, the grip 2 and a bottom end of the portable electronic product 1 are supported on a horizontal supporting surface 5. If necessary, with further reference to FIG. 5, the assembly of the portable electronic product 1 and the hand-held support can be placed on the horizontal supporting surface 5, in such a manner that the grip 2 and one of the clamping portions 311 of the clamping seat 3 are supported on the horizontal supporting surface 5. As such, the portable electronic product 1 can be supported on the horizontal supporting surface 5 by the hand-held support, so as to rotate a display panel of the portable electronic product to an inclined position, thereby resulting in convenience during use of the portable electronic product 1.

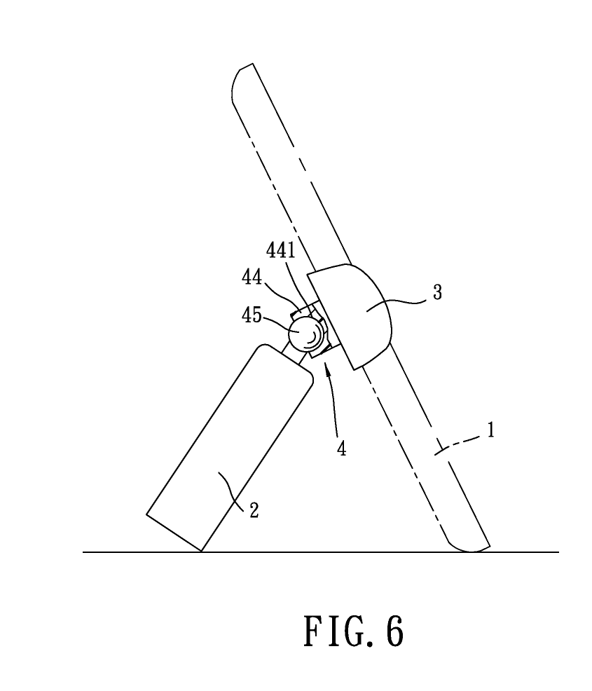

Referring to FIG. 6, the second preferred embodiment of a hand-held support according to this invention is generally identical to the first preferred embodiment in structure, and has a grip 2, a clamping seat 3 and a connecting mechanism 4. Unlike the first preferred embodiment, the connecting mechanism 4 includes an engaging block 44 disposed on the clamping seat 3, and a ball 45 disposed on the grip 2. The engaging block 44 is formed with an engaging groove 441 for engagement with the ball 45 to constitute a universal joint. In such a manner, this embodiment serves the same purpose of the first preferred embodiment.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A hand-held support adapted for supporting a portable electronic product, the electronic product having two opposite sides, said hand-held support comprising a grip, a clamping seat adapted for clamping the electronic product in such a manner to allow the electronic product to be removed forcibly therefrom, and a connecting mechanism for interconnecting said grip and said clamping seat in such a manner to allow for adjustment of a relative angle between said grip and said clamping seat, said clamping seat including a clamping wall having two clamping portions that are opposite to each other and that are adapted to contact respectively the sides of the electronic product for clamping the electronic product therebetween, and a base portion interconnecting said clamping portions.

2. The hand-held support as claimed in claim 1, wherein said clamping seat further include a pivot block, and said grip includes a pivot head, said connecting mechanism including a connecting block, a first pivot pin extending through said pivot block of said clamping seat and said connecting block, and a second pivot pin extending rotatably through said pivot head of said grip and said connecting block.

3. The hand-held support as claimed in claim 2, wherein said first and second pivot pins are perpendicular to each other.

4. The hand-held support as claimed in claim 1, wherein said base portion of said clamping wall is formed with a plurality of open-ended slots so as to increase resilience of said clamping portions.

5. The hand-held support as claimed in claim 4, wherein said base portion of said clamping seat has opposite front and rear side surfaces, said front side surface being adapted for contact with the electronic product, said open-ended slots being formed in said front and rear side surfaces.

6. The hand-held support as claimed in claim 4, wherein said clamping seat further includes at least one pad attached fixedly to said clamping seat and extending across a junction between said base portion and one of said clamping portions.

7. The hand-held support as claimed in claim 5, wherein each of said clamping portions of said clamping seat is formed with a retaining flange that is disposed at an end thereof distal from said base portion and that has an engaging surface, which faces said front side surface and which is adapted for contact with the electronic product.

8. The hand-held support as claimed in claim 1, wherein said connecting mechanism includes an engaging block disposed on one of said grip and said clamping seat, and a ball disposed on the other of said grip and said clamping seat, said engaging block being formed with an engaging groove for engagement with said ball to constitute a universal joint.
